(19) United States
(12) Patent Application Publication
(10) Pub. No.: US 2018/0204929 A1
(43) Pub. Date: Jul. 19, 2018

(54) METAL GATE FORMATION USING AN ENERGY REMOVAL FILM

(71) Applicant: GLOBALFOUNDRIES Inc., Grand Cayman (KY)

(72) Inventors: Shiv K. Mishra, Mechanicville, NY (US); Sunil K. Singh, Mechanicville, NY (US)

(21) Appl. No.: 15/407,407

(22) Filed: Jan. 17, 2017

(51) Int. Cl. H01L 29/66; H01L 21/321; H01L 21/283; H01L 21/768; H01L 21/324; H01L 21/762; H01L 29/49

(52) U.S. Cl. CPC H01L 29/66568; H01L 21/32115; H01L 21/283; H01L 29/4966; H01L 21/324; H01L 21/76224; H01L 29/665; H01L 21/76895

(57) ABSTRACT

Structures for a field-effect transistor and methods for forming a field-effect transistor. An interlayer dielectric layer is formed on a substrate. An energy removal film is formed on the interlayer dielectric layer, and at least one metal gate layer is formed on the energy removal film. After the at least one metal gate layer is polished, the energy removal film is removed from the interlayer dielectric layer. The removal of the energy removal film may remove metal residues generated by the polishing of the at least one metal gate layer so that the top surface of the interlayer dielectric layer is not contaminated by the metal residues.

### BACKGROUND

The present invention relates to semiconductor device fabrication and integrated circuits and, more specifically, to structures for a field-effect transistor and methods for forming a field-effect transistor.

Device structures for a field-effect transistor include a source, a drain, a channel region of semiconductor material arranged between the source and drain, and a gate structure including a gate electrode and a gate dielectric separating the gate electrode from the channel region. A gate voltage applied to the gate electrode is used to provide switching that selectively connects the source and drain to each other through the channel region.

In a replacement metal gate process for forming a field-effect transistor, metal layers are deposited to fill spacer-lined recesses in an interlayer dielectric layer and thereby form gate electrodes. Sections of the metal layers covering the top surface of the interlayer dielectric layer in a field area are nominally removed by polishing. However, as an artifact of polishing, the top surface of the interlayer dielectric layer may be contaminated by metal residues originating from the metal layers. These metal residues, which are highly conductive, can produce short circuits, during device operation, between the metal gate and the trench silicide that is formed on the adjacent source or drain.

Improved structures for a field-effect transistor and methods for forming a field-effect transistor are needed.

### SUMMARY

In an embodiment of the invention, a method includes forming an interlayer dielectric layer on a substrate, forming an energy removal film on the interlayer dielectric layer, forming at least one metal gate layer on the energy removal film, and polishing the at least one metal gate layer. After the at least one metal gate layer is polished, the energy removal film is removed from the interlayer dielectric layer. The removal of the energy removal film may remove metal residues generated by the polishing of the at least one metal gate layer so that the top surface of the interlayer dielectric layer is not contaminated by the metal residues.

In an embodiment of the invention, a structure includes an interlayer dielectric layer on a substrate, and a gate electrode projecting vertically through the interlayer dielectric layer and above a top surface of the interlayer dielectric layer. The structure further includes a cap dielectric layer on the top surface of the interlayer dielectric layer. The gate electrode extends vertically into the cap dielectric layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a portion of a substrate at successive fabrication stages of a processing method in accordance with embodiments of the invention.

### DETAILED DESCRIPTION

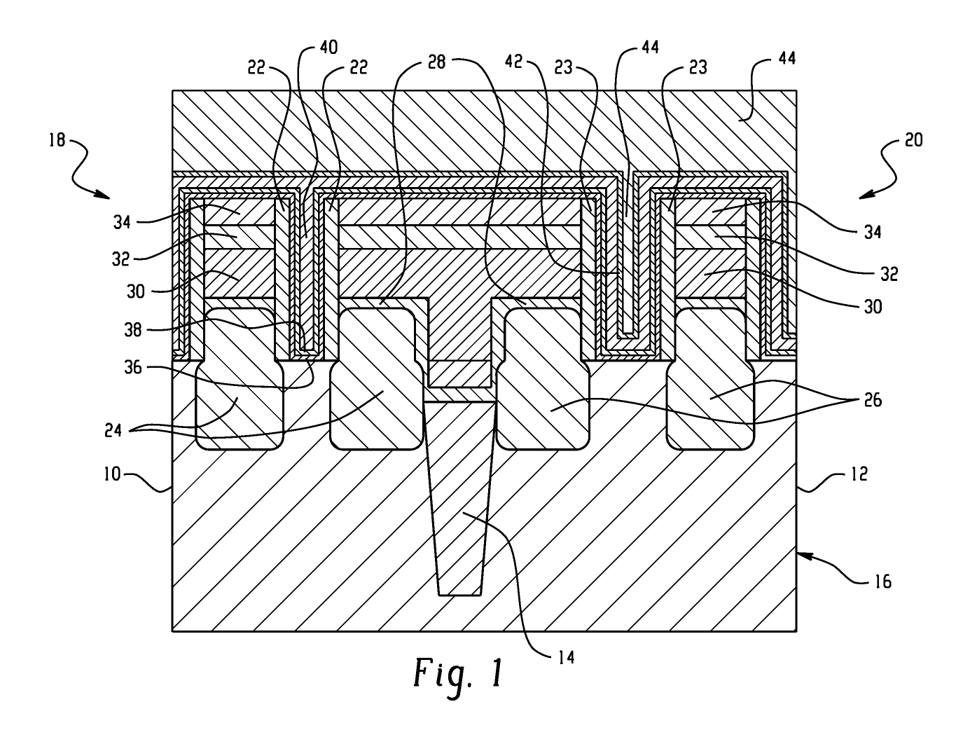

With reference to FIG. 1 and in accordance with embodiments of the invention, active device regions 10, 12 include respective semiconductor bodies that are separated and surrounded by trench isolation 14 formed in a substrate 16. The substrate 16 may be a bulk substrate or, alternatively, a device layer of a semiconductor-on-insulator (SOI) substrate. The trench isolation 14 may be formed by a shallow trench isolation (STI) technique in which trenches are formed in the substrate 16 and then filled with an electrical insulator, such as silicon dioxide (SiO₂), that is deposited and planarized with, for example, chemical mechanical polishing (CMP).

A device structure 18 formed by front-end-of-line (FEOL) processing is associated with the active device region 10. The device structure 18 includes non-conductive spacers 22 and raised source/drain regions 24 that are located adjacent to the non-conductive spacers 22. A device structure 20 formed by FEOL processing is associated with the active device region 12. The device structure 20 includes non-conductive spacers 23 and raised source/drain regions 26 that are located adjacent to the non-conductive spacers 23. As used herein, the term “source/drain region” refers to a doped region of semiconductor material that can function as either a source or a drain of a field-effect transistor.

A conformal layer 28 is deposited as a liner that covers the trench isolation 14, the source/drain regions 24 in active device region 10, and the source/drain regions 26 in active device region 12. An interlayer dielectric layer 30 is located in the gaps above the trench isolation 14, the source/drain regions 24, and the source/drain regions 26.

An energy removal film 32 is located on the interlayer dielectric layer 30, and a dielectric layer 34 is located on the energy removal film 32. The energy removal film 32 is located vertically between the interlayer dielectric layer 30 and the dielectric layer 34.

The non-conductive spacers 22, 23 may be formed by shaping a conformal layer with an anisotropic etching process, such as reactive ion etching (RIE), that preferentially removes the dielectric material from horizontal surfaces. In a replacement gate process, dummy gates (not shown) are formed as sacrificial structures on the substrate 16, and the conformal layer covers the dummy gates prior to the performance of the etching process.

The source/drain regions 24, 26 are formed after the non-conductive spacers 22, 23 are formed. The source/drain regions 24 may be formed by an epitaxial growth process at the designated locations adjacent to the non-conductive spacers 22 and a dummy gate occupying the space between the non-conductive spacers 22. The source/drain regions 26 may be formed by an epitaxial growth process at the designated locations adjacent to the non-conductive spacers 23 and a dummy gate occupying the space between the non-conductive spacers 23. Epitaxial growth processes deposit sections of a semiconductor material, such as silicon-germanium alloy (SiGe), and may be selective epitaxial growth (SEG) processes in which semiconductor material nucleates for epitaxial growth on semiconductor surfaces, but does not nucleate for epitaxial growth from insulator surfaces. A patterned conformal dielectric layer may be applied as a block mask to cover active device region 12 when the raised source/drain regions 24 are grown, and another patterned conformal dielectric layer may be applied as a block mask to cover active device region 10 when the raised source/drain regions 26 are grown.

The source/drain regions 24 may be doped during growth to impart a conductivity type to the constituent semiconductor material. The source/drain regions 26 may be doped during growth to impart a conductivity type to the constituent semiconductor material that is opposite to the conductivity type of the source/drain regions 24. For example, the semiconductor material of the raised source/drain regions 24 may incorporate a p-type dopant selected from Group III of the Periodic Table (e.g., boron (B)) that imparts p-type conductivity, and the semiconductor material of the raised source/drain regions 24 may incorporate an n-type dopant from Group V of the Periodic Table (e.g., phosphorus (P) or arsenic (As)) that imparts n-type conductivity.

The conformal layer 28 is formed after the source/drain regions 24, 26 are formed. The conformal layer 28 may be comprised of a dielectric material, such as silicon nitride (Si₃N₄), deposited by chemical vapor deposition (CVD). The interlayer dielectric layer 30 is formed after the conformal layer 28 is formed. The interlayer dielectric layer 30 may be composed of a flowable oxide deposited by CVD or Tonen Silazene (TOSZ) formed by spin coating. The dielectric layer 34, which is formed after the energy removal film 32 is formed, may be composed of a dielectric material, such as a high-density plasma (HDP) oxide.

The energy removal film 32 is formed after the interlayer dielectric layer 30 is formed and before the dielectric layer 34 is formed. The energy removal layer 32 is arranged vertically between the interlayer dielectric layer 30 and the dielectric layer 34. The energy removal film 32, which is sacrificial, is constituted by a material that decomposes upon being heated and/or exposed to radiation from an energy source, such as ultraviolet (UV) radiation from a UV energy source. The energy removal film 32 may be an organic compound, such as a silicon-based organic (CxHy) compound, and may be deposited by CVD or a spin-on process. In an embodiment, the energy removal film 32 may be comprised of, or similar in composition and chemical properties, to a porogen, which is a sacrificial organic-based material used to generate or form pores in a low-k dielectric film after removal.

After the conformal layer 28, the interlayer dielectric layer 30, the energy removal film 32, and the dielectric layer 34 are formed, the dielectric layer 34 may be planarized using, for example, CMP. The planarization may open the top surface of the dummy gates for removal to define cavities and replacement by functional gate structures.

After the dummy gates are removed to define cavities, a multi-layer gate stack is deposited that follows the contour of the cavities between the non-conductive spacers 22, 23 and the top surface of the dielectric layer 34. The gate stack includes a gate dielectric layer 36 comprised of an electrical insulator, such as a high-k dielectric material like hafnium oxide or hafnium oxynitride, deposited by CVD, atomic layer deposition (ALD), etc. The gate stack further includes a gate electrode layer 38 comprised of a metal, such as titanium nitride (TiN), a gate electrode layer 40 comprised of a metal, such as titanium aluminum carbide (TiAlC), a gate electrode layer 42 comprised of a metal, such as titanium nitride (TiN), and a gate electrode layer 44 comprised of a metal, such as tungsten (W). The gate electrode layers 38, 40, 42, 44 may be deposited by physical vapor deposition (PVD), ALC, CVD, etc., and one or more of the gate electrode layers 38, 40, 42, 44 may function as work function metal layers. The gate electrode layer 44 may be planarized with, for example, CMP to remove topography arising from filling the cavities between the non-conductive spacers 22, 23 that are opened with the dummy gates are removed.

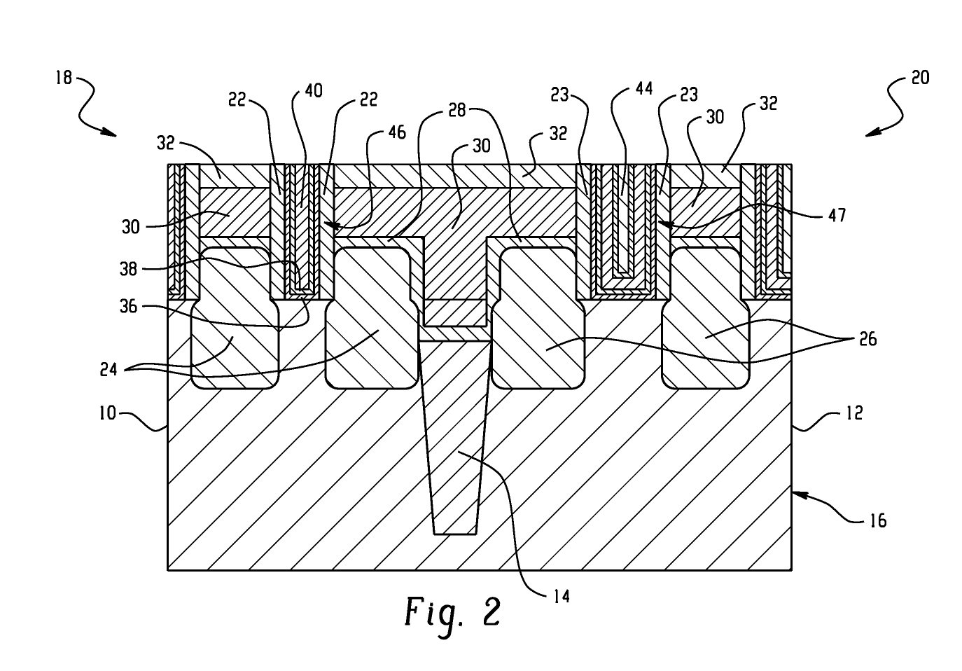

With reference to FIG. 2 in which like reference numerals refer to like features in FIG. 1 and at a subsequent fabrication stage, the gate dielectric layer 36 and the gate electrode layers 38, 40, 42, 44 are removed from the field area adjacent to the cavities with one or more CMP processes. A gate electrode, generally indicated by reference numeral 46, is defined by the planarization in the cavity interior of the non-conductive spacers 22, and a gate electrode, generally indicated by reference numeral 48, is defined by the planarization in the cavity interior of the non-conductive spacers 23. The dielectric layer 34 is removed by polishing to expose the energy removal film 32, and the energy removal film 32 operates as a polish stop. Each CMP operation may be conducted with a commercial tool using polishing pads and slurries selected to polish the targeted material.

During the polishing processes, metal residues from the polished-away sections of the gate electrode layers 38, 40, 42, 44 become associated with the energy removal film 32. For example, metal residues (e.g., titanium residues) from the gate electrode layers 38, 40, 42 may become positioned on the top surface of the energy removal film 32 and/or embedded in the energy removal film 32 at its top surface.

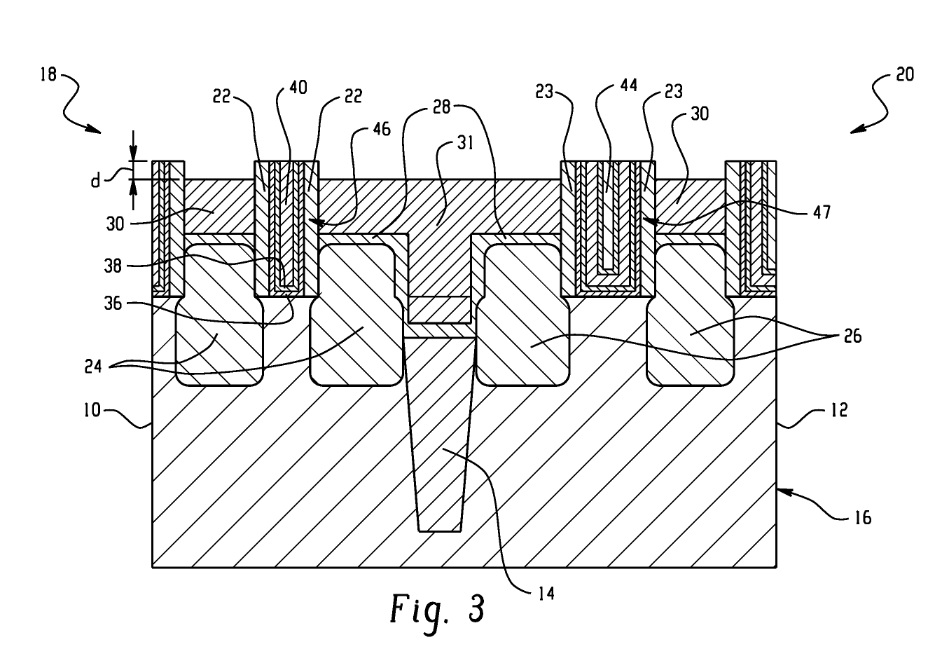

With reference to FIG. 3 in which like reference numerals refer to like features in FIG. 2 and at a subsequent fabrication stage, the energy removal film 32 is selectively removed from the interlayer dielectric layer 30. To that end, the energy removal film 32 may be removed by exposure to a thermal treatment and/or exposure to radiation from an energy source, such as ultraviolet (UV) radiation from a UV energy source. The material constituting the energy removal film 32 decomposes upon being heated to a temperature that is greater than ambient temperature while exposed to UV radiation. In an embodiment, the temperature for the thermal treatment may be 400° C. The products of the decomposition of the energy removal film 32 may be gaseous and are released into the environment surrounding the substrate 16. The metal residues associated with the energy removal film 32 are also removed, along with the decomposition products, into the environment surrounding the substrate 16. The environment surrounding the substrate 16 may be evacuated to dispose of the metal residues.

After the energy removal film 32 is removed, a top surface 31 of the interlayer dielectric layer 30 is revealed. The thickness of the interlayer dielectric layer 30 is not changed by the removal of the energy removal film 32. The height of the gate electrodes 46, 47 is not changed by the removal of the energy removal film 32. The gate electrodes 46, 47 project above the top surface 31 of the interlayer dielectric layer 30 by a predetermined distance, d, that is equal to the thickness of the energy removal film 32. Stated differently, the top surface 31 of the interlayer dielectric layer 30 is recessed below the top surfaces of the gate electrodes 46, 47 by a predetermined distance (i.e., step height) that is equal to the thickness of the energy removal film 32. The recessing of the top surface 31 of the interlayer dielectric layer 30 through removal of the energy removal film 32 is provided without affecting the gate height uniformity and without the use of an etch-back process.

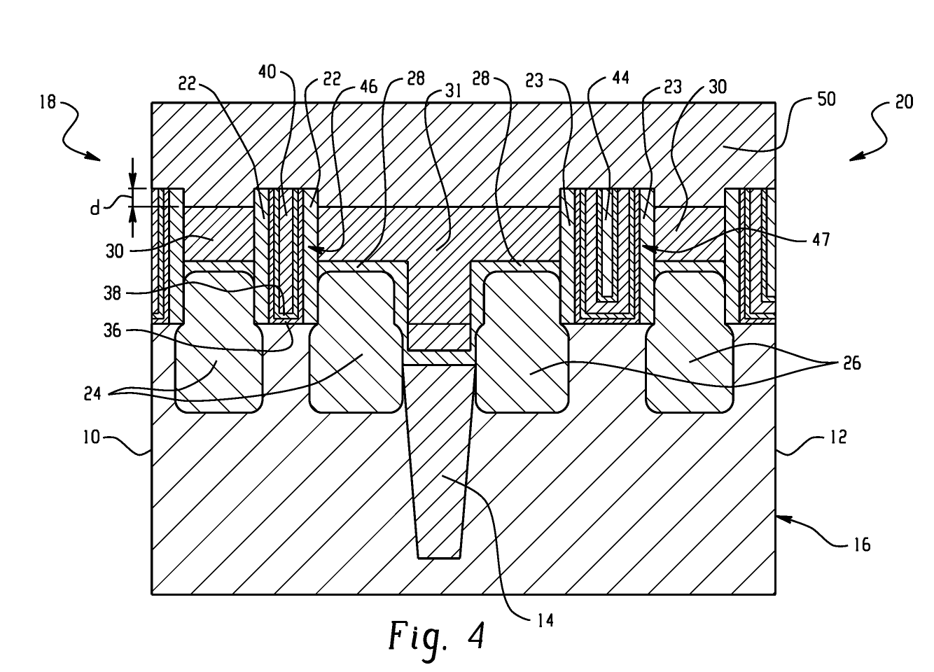

With reference to FIG. 4 in which like reference numerals refer to like features in FIG. 3 and at a subsequent fabrication stage, silicidation, middle-of-line (MOL), and back-end-of-line (BEOL) processing follows, which includes formation of contacts and wiring for a local interconnect structure, and formation of dielectric layers, via plugs, and wiring for an interconnect structure coupled by the interconnect wiring with the field-effect transistors. In particular, a dielectric layer 50 is formed as a cap on the interlayer dielectric layer 30. The electrical insulator constituting the cap dielectric layer 50 may be an oxide of silicon (e.g., silicon dioxide) deposited by CVD and, in an embodiment, may be an oxide film deposited by sub-atmospheric CVD utilizing tetraethylorthosilicate (TEOS) and ozone as reactant gases.

The cap dielectric layer 50 fills the space between the gate electrodes 46, 47 and also covers the gate electrodes 46, 47. Because the top surface 31 of the interlayer dielectric layer 30 is recessed relative to the gate electrodes 46, 47 after the energy removal film 32 is removed, the cap dielectric layer 50 fills the space above the recessed top surface 31. The gate electrodes 46, 47 extend into the cap dielectric layer 50. The space between the recessed top surface 31 and the top surfaces of the gate electrodes 46, 46 is filled by the cap dielectric layer 50, which may differ in composition from the interlayer dielectric layer 30.

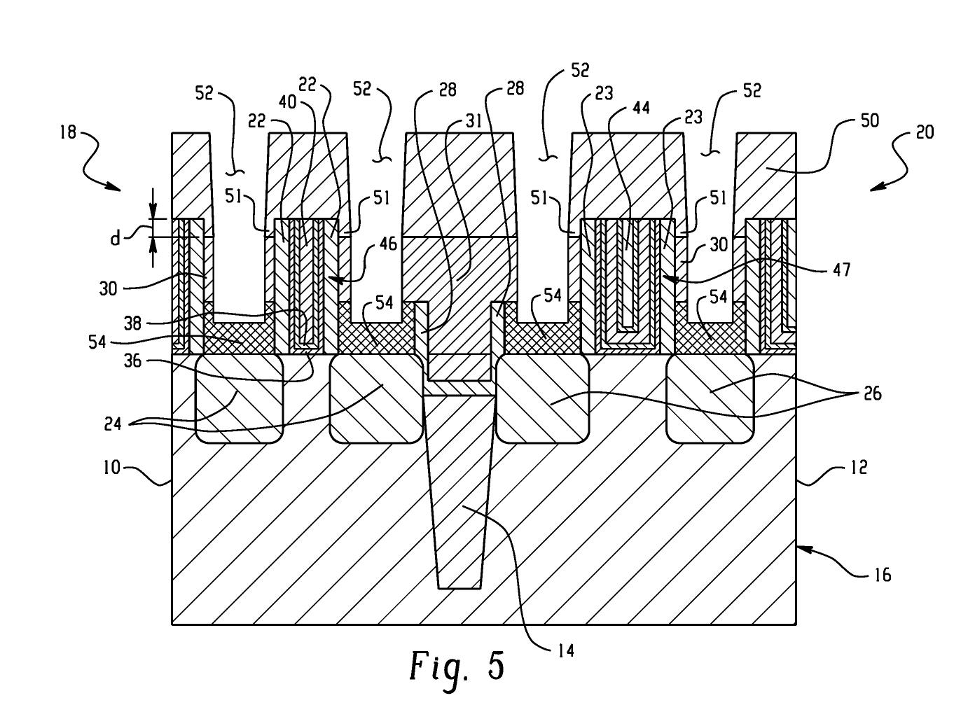

With reference to FIG. 5 in which like reference numerals refer to like features in FIG. 4 and at a subsequent fabrication stage, contact openings 52 are formed that extend vertically through the cap dielectric layer 50 and the interlayer dielectric layer 30 to the source/drain regions 24 and the source/drain regions 26. The conformal layer 28 is removed from the respective top surfaces of the source/drain regions 24 and the source/drain regions 26 over the area of the contact openings 52. A portion 51 of the cap dielectric layer 50 is located between the gate electrodes 46, 47 and the contact openings 52, and has a height that is equal to the distance, d, that the gate electrodes 46, 47 project above the top surface 31 of the interlayer dielectric layer 30.

A silicide layer 54 is formed on the top surfaces of the source/drain regions 24 and the source/drain regions 26 at the locations of the contact openings 52. The silicide layer 54 may be formed by a silicidation process involving depositing a conformal layer of a silicide-forming metal, followed by one or more annealing steps to form a silicide phase by reacting the layer of silicide-forming metal and the semiconductor material (e.g., silicon-germanium) of the source/drain regions 24 and the source/drain regions 26 that are in a contacting relationship with the silicide-forming metal. The silicide-forming metal in contact with dielectric material does not react with the dielectric material. Candidate materials for the silicide-forming metal include, but are not limited to, titanium (Ti), cobalt (Co), nickel (Ni), or another metal capable of reacting with silicon to form a low-resistivity, thermally-stable silicide. The silicide-forming metal may be deposited by, for example, CVD or PVD. Before annealing, a capping layer comprised of a metal nitride, such as sputter-deposited titanium nitride (TiN), may be applied to cap the silicide-forming metal. An initial annealing step of the silicidation process may form a metal-rich silicide that consumes the silicide-forming metal and then form silicides of lower metal content that grow by consuming the metal-rich silicides. Following the initial annealing step, any remaining silicide-forming metal and the optional capping layer may be removed by wet chemical etching. The silicide layer may then be subjected to an additional annealing step at a higher temperature to form a lower-resistance silicide phase of higher metal content.

The removal of the metal residues using the energy removal film 32 provides a higher margin for short circuits between the gate electrodes 46, 47 and the silicide layer 54 that would otherwise be caused by the metal residues. Specifically, the metal residues, if not removed through the use of the energy removal film 32, could provide conductive paths resulting in the occurrence of a short circuit between gate electrodes 46, 47 and the silicide layer 54. The introduction of the energy removal film 32 above the interlayer dielectric layer 30 also permits polishing time to be shortened, which tightens control over gate height.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature may be “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
forming an interlayer dielectric layer on a substrate;
forming an energy removal film on the interlayer dielectric layer;
forming at least one metal gate layer on the energy removal film;
polishing the at least one metal gate layer; and
after the at least one metal gate layer is polished, removing the energy removal film from the interlayer dielectric layer by exposing the energy removal film to radiation from an energy source.

2. The method of claim 1 wherein metal residues generated by the polishing of the at least one metal gate layer are located on the energy removal film.

3. The method of claim 1 wherein the interlayer dielectric layer includes a trench, and a gate electrode is formed from the at least one metal gate layer in the trench following polishing.

4. The method of claim 3 wherein the energy removal film operates as a polish stop when the at least one metal gate layer is polished, and the interlayer dielectric layer is recessed relative to the gate electrode to define a recess after the energy removal film is removed from the interlayer dielectric layer.

5. The method of claim 4 further comprising:
forming a cap dielectric layer on the interlayer dielectric layer that fills the recess; and
planarizing the cap dielectric layer.

6. The method of claim 5 further comprising:
forming a contact opening extending through the cap dielectric layer and the interlayer dielectric layer to a source/drain region adjacent to the gate electrode.

7. The method of claim 1 wherein the energy removal film operates as a polish stop when the at least one metal gate layer is polished, and the interlayer dielectric layer is recessed, after the energy removal film is removed, relative to a gate electrode formed from the at least one metal gate layer, after polishing, to define a recess.

8. The method of claim 7 further comprising:
forming a cap dielectric layer on the interlayer dielectric layer that fills the recess; and
planarizing the cap dielectric layer.

9. A method comprising:
forming an interlayer dielectric layer on a substrate;
forming an energy removal film on the interlayer dielectric layer;
forming at least one metal gate layer on the energy removal film;
polishing the at least one metal gate layer; and
after the at least one metal gate layer is polished, removing the energy removal film from the interlayer dielectric layer by elevating a temperature of the energy removal film above ambient temperature.

10. The method of claim 9 wherein removing the energy removal film further comprises:
while the temperature of the energy removal film is elevated, exposing the energy removal film to radiation from an energy source to assist in removing the energy removal film.

11. The method of claim 10 wherein the radiation is ultraviolet (UV) radiation, and the energy source is an ultraviolet (UV) energy source.

12. (canceled)

13. The method of claim 1 wherein the radiation is ultraviolet (UV) radiation, and the energy source is an ultraviolet (UV) energy source.

14. The method of claim 1 wherein the at least one metal gate layer includes a plurality of metal gate layers, and metal residues generated by the polishing of the plurality of metal gate layers are located on the energy removal film.

15. The method of claim 1 further comprising:
before the at least one metal gate layer is formed, forming a sacrificial dielectric layer on the energy removal film,
wherein the energy removal film is located between the sacrificial dielectric layer and the interlayer dielectric layer, the at least one metal gate layer is formed on the sacrificial dielectric layer, and the sacrificial dielectric layer is removed when the at least one metal gate layer is polished.

16. The method of claim 1 wherein the energy removal film comprises a silicon-based organic compound.

17-20. (canceled)

21. method of claim 9 further comprising:
before the at least one metal gate layer is formed, forming a sacrificial dielectric layer on the energy removal film,
wherein the energy removal film is located between the sacrificial dielectric layer and the interlayer dielectric layer, the at least one metal gate layer is formed on the sacrificial dielectric layer, and the sacrificial dielectric layer is removed when the at least one metal gate layer is polished.

22. The method of claim 9 wherein the energy removal film comprises a silicon-based organic compound.

23. The method of claim 9 wherein the interlayer dielectric layer includes a trench, and a gate electrode is formed from the at least one metal gate layer in the trench following polishing.

24. The method of claim 23 wherein the energy removal film operates as a polish stop when the at least one metal gate layer is polished, and the interlayer dielectric layer is recessed relative to the gate electrode to define a recess after the energy removal film is removed from the interlayer dielectric layer.

25. The method of claim 24 further comprising:
forming a cap dielectric layer on the interlayer dielectric layer that fills the recess;
planarizing the cap dielectric layer; and
forming a contact opening extending through the cap dielectric layer and the interlayer dielectric layer to a source/drain region adjacent to the gate electrode.
